(19) United States
(12) Patent Application Publication
(10) Pub. No.: US 2025/0386440 A1
(43) Pub. Date: Dec. 18, 2025

(54) REINFORCEMENT PLATE, DISPLAY ASSEMBLY, AND TERMINAL

(71) Applicant: Huawei Technologies Co., Ltd., Shenzhen (CN)

(72) Inventors: Zhenmin Xiong, Shenzhen (CN); Heng Li, Shanghai (CN); Shijun Zhang, Wuhan (CN); Shengli Yang, Wuhan (CN); Xinyi Zhang, Dongguan (CN); Wei Tang, Wuhan (CN); Xiang Che, Shanghai (CN); Xiong Hu, Wuhan (CN); Yuexing Zhan, Dongguan (CN); Yanbin Feng, Wuhan (CN)

(21) Appl. No.: 19/303,775

(22) Filed: Aug. 19, 2025

Related U.S. Application Data
(63) Continuation of application No. PCT/CN2024/077621, filed on Feb. 19, 2024.

(30) Foreign Application Priority Data
May 17, 2023 (CN) 202310565542.2

(51) Int. Cl. H05K 5/02; B32B 7/12; B32B 15/14

(52) U.S. Cl. CPC H05K 5/02; B32B 7/12; B32B 15/14; B32B 2260/021; B32B 2260/046; B32B 2262/106; B32B 2307/202; B32B 2307/206; B32B 2307/302; B32B 2457/206

(57) ABSTRACT

A reinforcement plate, a display assembly, and a terminal, the reinforcement plate including a carbon fiber composite layer and a first conducting layer. The carbon fiber composite layer includes a resin layer and a carbon fiber filament disposed in the resin layer. The carbon fiber composite layer includes a first surface. The first surface exposes a first part of the carbon fiber filament, and the first conducting layer is located on the first surface and is in contact with the first part of the carbon fiber filament.

### CROSS-REFERENCE TO RELATED APPLICATIONS

This application is a continuation of International Application No. PCT/CN2024/077621, filed on Feb. 19, 2024, which claims priority to Chinese Patent Application No. 202310565542.2, filed on May 17, 2023. The disclosures of the aforementioned applications are hereby incorporated by reference in their entireties.

### TECHNICAL FIELD

This application relates to the field of display technologies, and in particular, to a reinforcement plate, a display assembly, and a terminal.

### BACKGROUND

With development of display technologies, flexible displays are increasingly used in terminal devices. To maintain flatness and rigidity of screens of flexible displays in foldable terminal devices, reinforcement plates are generally disposed on non-display sides of the flexible displays. However, current reinforcement plates have unsatisfactory conducting properties and are with large weights.

### SUMMARY

Embodiments of this application provide a reinforcement plate, a display assembly, and a terminal, to address a problem that a reinforcement plate has an unsatisfactory conducting property and is with a large weight.

To achieve the foregoing objective, the following technical solutions are used in embodiments of this application.

According to a first aspect, a reinforcement plate is provided. The reinforcement plate includes a carbon fiber composite layer, a first conducting layer, and a second conducting layer. The carbon fiber composite layer includes a resin layer and a carbon fiber filament disposed in the resin layer. The carbon fiber composite layer includes a first surface and a second surface that are opposite to each other, the first surface exposes a first part of the carbon fiber filament, and the second surface exposes a second part of the carbon fiber filament. The first conducting layer is located on the first surface and is in contact with the first part of the carbon fiber filament. The second conducting layer is located on the second surface and is in contact with the second part of the carbon fiber filament. The first conducting layer and the second conducting layer are conducted through the carbon fiber composite layer.

In the reinforcement plate provided in this embodiment of this application, the carbon fiber composite layer including the carbon fiber filament is disposed. The first conducting layer is in contact with the first part of the carbon fiber filament, and the second conducting layer is in contact with the second part of the carbon fiber filament. Thanks to a good conducting property of the carbon fiber filament, the first conducting layer, the carbon fiber composite layer, and the second conducting layer in the reinforcement plate can form a good electrostatic conduction path. In this way, after the reinforcement plate is bonded to a display, static electricity on the display can be effectively led out and transmitted to the ground by using the reinforcement plate. This reduces or avoids adverse impact caused by the static electricity on the display, and ensures normal displaying of the display.

In addition, low density of the carbon fiber composite layer can contribute to low overall density of the reinforcement plate, thereby helping reduce a weight of the reinforcement plate, and reduce a weight of a display assembly and a weight of a terminal that use the reinforcement plate. In addition, a good heat conducting property of the carbon fiber composite layer contributes to a good heat conducting property of the reinforcement plate. Therefore, after the reinforcement plate is bonded to the display, heat is effectively dissipated from the display.

In some embodiments, the carbon fiber composite layer further includes a heat conducting material. The heat conducting material is disposed in the resin layer, a heat conductivity of the heat conducting material is higher than that of the carbon fiber filament, and density of the heat conducting material is lower than that of the carbon fiber filament.

In this embodiment of this application, the heat conducting material is disposed in the carbon fiber composite layer, and the heat conductivity of the heat conducting material is higher than that of the carbon fiber filament, so that both the carbon fiber composite layer and the reinforcement plate have a better heat conducting property. Therefore, after the reinforcement plate is bonded to the display, heat is better dissipated from the display. In addition, the density of the heat conducting material is lower than that of the carbon fiber filament, so that both the carbon fiber composite layer and the reinforcement plate have lower density, thereby further reducing a weight of the reinforcement plate.

In some embodiments, the heat conducting material is graphene.

In some embodiments, the carbon fiber filament includes a first carbon fiber filament and a second carbon fiber filament, and extension directions of the first carbon fiber filament and the second carbon fiber filament intersect. The carbon fiber composite layer includes a first subpart and a second subpart located on two sides of the first subpart. The first subpart includes the first carbon fiber filament or the second carbon fiber filament, and the second subpart includes the first carbon fiber filament and the second carbon fiber filament.

In this embodiment of this application, only one of the first carbon fiber filament and the second carbon fiber filament is disposed in the first subpart, and both the first carbon fiber filament and the second carbon fiber filament are disposed in the second subpart, so that flexibility of the first subpart is better than that of the second subpart, and rigidity of the second subpart is better than that of the first subpart. When the display supported by the reinforcement plate is a flexible display, the display may include a foldable region and two non-foldable regions that are respectively disposed on two sides of the foldable region. In this way, after the reinforcement plate is bonded to the display, the first part of the carbon fiber composite layer of the reinforcement plate can be folded along with the foldable region of the display, and the second part of the carbon fiber composite layer of the reinforcement plate can support the non-foldable regions of the display when the display is folded or unfolded.

In some embodiments, both the first conducting layer and the second conducting layer include a transition layer and a metal layer that are disposed in a stacked manner, the transition layer is located between the metal layer and the carbon fiber composite layer, and a material of the transition layer includes at least one of titanium, nickel, chromium, molybdenum, or tungsten.

In some embodiments, a projection of the first conducting layer on the first surface is an annulus. The annulus includes an inner edge and an outer edge, and the outer edge of the annulus coincides with an edge of the first surface.

In some embodiments, a width of the annulus is less than or equal to 20 millimeters.

In some embodiments, the reinforcement plate further includes a first insulation layer, and the first insulation layer is located on the first surface. The first conducting layer surrounds the first insulation layer and is in contact with the first insulation layer.

In some embodiments, the reinforcement plate further includes a conductive adhesive layer. The conductive adhesive layer is located on a side that is of the first conducting layer and that is away from the carbon fiber composite layer.

In some embodiments, a surface that is of the conductive adhesive layer and that is away from the carbon fiber composite layer is flush with a surface that is of the first insulation layer and that is away from the carbon fiber composite layer.

According to a second aspect, a preparation method for a reinforcement plate is provided. The preparation method includes the following steps: A carbon fiber composite layer is prepared, where the carbon fiber composite layer includes a resin layer and a carbon fiber filament disposed in the resin layer. The carbon fiber composite layer includes a first surface and a second surface that are opposite to each other, the first surface exposes a first part of the carbon fiber filament, and the second surface exposes a second part of the carbon fiber filament. A first conducting layer is formed on the first surface, and the first conducting layer is in contact with the first part of the carbon fiber filament. A second conducting layer is formed on the second surface, and the second conducting layer is in contact with the second part of the carbon fiber filament. The first conducting layer and the second conducting layer are conducted through the carbon fiber composite layer.

In some embodiments, preparing the carbon fiber composite layer includes: preparing a carbon fiber plate by using the carbon fiber filament and a resin material, where the carbon fiber plate includes a first surface and a second surface that are disposed opposite to each other. Roughening processing is performed on the first surface and the second surface until the first part and the second part of the carbon fiber filament are exposed.

In some embodiments, preparing the carbon fiber composite layer includes: combining graphene and the carbon fiber filament by using a surface in-situ composite process or a hybrid weaving process. A carbon fiber plate is prepared by using the resin material and the graphene and the carbon fiber filament that are combined, where the carbon fiber plate includes a first surface and a second surface that are disposed opposite to each other. Roughening processing is performed on the first surface and the second surface until the first part and the second part of the carbon fiber filament are exposed.

According to a third aspect, a display assembly is provided. The display assembly includes a display and the reinforcement plate described in any one of the foregoing embodiments, and the reinforcement plate is located on a non-display side of the display and is bonded to the display.

In some embodiments, the display is a flexible display, the display includes a foldable region and two non-foldable regions, and the two non-foldable regions are respectively located on two sides of the foldable region. The reinforcement plate includes a carbon fiber composite layer, the carbon fiber composite layer includes a first subpart and a second subpart, the first subpart corresponds to the foldable region, and the second subpart corresponds to the non-foldable region.

In some embodiments, the display includes a substrate, a light emitting device, a second insulation layer, and a metal sheet. The light emitting device is located on the substrate. The second insulation layer is located on a side that is of the substrate and that is away from the light emitting device. The metal sheet is located on a side that is of the second insulation layer and that is away from the substrate. The metal sheet is bonded to the reinforcement plate.

According to a fourth aspect, a terminal is provided. The terminal includes a housing and the display assembly according to any one of the foregoing embodiments, and the display assembly is disposed in the housing.

In some embodiments, the terminal further includes a middle frame and an electrical connector. The middle frame is disposed in the housing, and is located on a non-display side of the display assembly. The electrical connector is located between the display assembly and the middle frame, and a reinforcement plate of the display assembly is connected to the middle frame through the electrical connector.

For technical effects brought by any design manner of the second aspect to the fourth aspect, refer to technical effects brought by different design manners of the first aspect, and details are not described herein again.

### BRIEF DESCRIPTION OF THE DRAWINGS

To describe technical solutions in this application more clearly, the following briefly describes accompanying drawings for describing some embodiments of this application. It is apparent that the accompanying drawings in the following descriptions are merely accompanying drawings in some embodiments of this application. For a person of ordinary skill in the art, other drawings may also be derived from these drawings. In addition, the accompanying drawings in the following descriptions may be considered as diagrams, and are not intended to limit an actual size of a product, an actual procedure of a method, an actual time sequence of a signal, and the like in embodiments of this application.

FIG. 1 is a diagram of a structure of a reinforcement plate according to an embodiment of this application;

FIG. 2 is a diagram of a microstructure of a first surface or a second surface of a reinforcement plate according to an embodiment of this application;

FIG. 3 is a diagram of a structure of a carbon fiber composite layer according to an embodiment of this application;

FIG. 4 is a diagram of a structure of another carbon fiber composite layer according to an embodiment of this application;

FIG. 5 is a diagram of a three-dimensional structure of a reinforcement plate according to an embodiment of this application;

FIG. 6 is a cross sectional schematic view of the reinforcement plate provided in FIG. 5 at A-A′;

FIG. 7 is a schematic top view of a reinforcement plate according to an embodiment of this application;

FIG. 8 is a diagram of a three-dimensional structure of another reinforcement plate according to an embodiment of this application;

FIG. 9 is a cross sectional schematic view of the reinforcement plate provided in FIG. 8 at B-B′;

FIG. 10 is a flowchart of a preparation method for a reinforcement plate according to an embodiment of this application;

FIG. 11 is a flowchart of a preparation method for another reinforcement plate according to an embodiment of this application;

FIG. 12A is a diagram of a structure of a carbon fiber plate according to an embodiment of this application;

FIG. 12B is a diagram of a microstructure of a first surface or a second surface of a carbon fiber plate according to an embodiment of this application;

FIG. 13 is a diagram of a structure of a carbon fiber composite layer according to an embodiment of this application;

FIG. 14 is a flowchart of a preparation method for still another reinforcement plate according to an embodiment of this application;

FIG. 15A is a diagram of a structure of another reinforcement plate according to an embodiment of this application;

FIG. 15B is a diagram of a microstructure of a first conducting layer or a second conducting layer according to an embodiment of this application;

FIG. 16 is a diagram of a structure of still another reinforcement plate according to an embodiment of this application;

FIG. 17 is a diagram of a structure of yet another reinforcement plate according to an embodiment of this application;

FIG. 18 is a diagram of a structure of a display assembly according to an embodiment of this application;

FIG. 19 is a diagram of a structure of another display assembly according to an embodiment of this application;

FIG. 20 is a diagram of a structure of still another display assembly according to an embodiment of this application;

FIG. 21 is a diagram of a structure of a terminal according to an embodiment of this application; and

FIG. 22 is a diagram of a structure of another terminal according to an embodiment of this application.

### DETAILED DESCRIPTION OF ILLUSTRATIVE EMBODIMENTS

The following describes technical solutions in embodiments of this application with reference to the accompanying drawings in embodiments of this application. Unless otherwise specified, “/” in descriptions of this application represents an “or” relationship between associated objects. For example, A/B may represent A or B.

In this application, “and/or” only describes an association relationship between associated objects, and represents that three relationships may exist. For example, A and/or B may represent the following three cases: A exists alone, both A and B exist, and B exists alone, where A and B may be singular or plural.

In the descriptions of this application, unless otherwise specified, “a plurality of” means two or more than two. At least one of the following items (pieces) or a similar expression thereof indicates any combination of these items, including a single item (piece) or any combination of a plurality of items (pieces). For example, at least one (piece) of a, b, or c may represent: a, b, c, a-b, a-c, b-c, or a-b-c, where a, b, and c may be singular or plural.

As used herein, “about” includes the stated values and the average values within an acceptable deviation range of a particular value, where the acceptable deviation range is determined by a person of ordinary skill in the art by considering an error (namely, a limitation of a measurement system) related to measurement being discussed and measurement of a specific quantity.

Example implementations are described with reference to sectional views and/or plane diagrams that are used as idealized example accompanying drawings. In the accompanying drawings, for clarity, thicknesses of layers and regions are increased. Thus, a change in a shape in the accompanying drawings due to, for example, manufacturing techniques and/or tolerances may be envisaged. Therefore, example implementations should not be construed as being limited to a shape of a region shown herein, but rather include shape deviations due to, for example, manufacturing. For example, an etching region shown as a rectangle typically has a curved characteristic. Therefore, the regions shown in the accompanying drawings are essentially examples, and their shapes are not intended to show actual shapes of regions of a device, and are not intended to limit a scope of the example implementations.

To clearly describe the technical solutions in embodiments of this application, terms such as “first” and “second” are used in embodiments of this application to distinguish between same items or similar items that provide basically same functions or purposes. A person skilled in the art may understand that the terms such as “first” and “second” do not limit a quantity or an execution sequence, and the terms such as “first” and “second” do not indicate a definite difference.

In addition, in embodiments of this application, the word “exemplary” or “for example” is used to represent giving an example, an illustration, or a description. Any embodiment or design scheme described as an “example” or “for example” in embodiments of this application should not be explained as being more preferred or having more advantages than another embodiment or design scheme. Exactly, use of the terms such as “example” or “for example” is intended to present a related concept in a specific manner for ease of understanding.

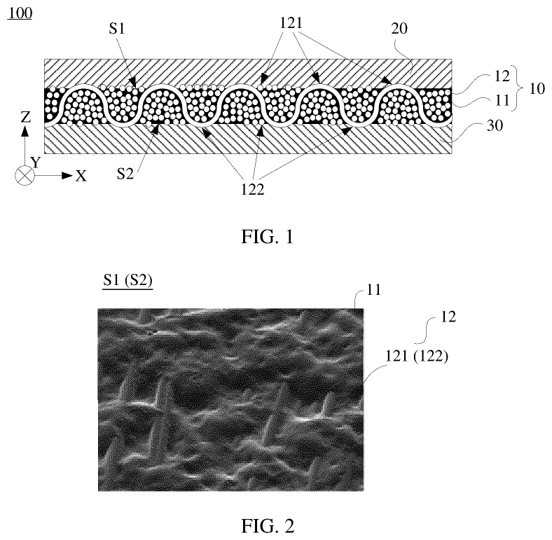

As shown in FIG. 1, an embodiment of this application provides a reinforcement plate 100, configured to support a display. The reinforcement plate 100 includes a carbon fiber composite layer 10, a first conducting layer 20, and a second conducting layer 30.

FIG. 2 is a diagram of a microstructure of the carbon fiber composite layer 10 obtained through electron microscope observation. As shown in FIG. 2, the carbon fiber composite layer 10 includes a resin layer 11 and a carbon fiber filament 12 disposed in the resin layer 11.

A resin material of the resin layer 11 may include thermoplastic resin, or may be thermosetting resin. For example, the resin material may include any one or more of epoxy resin, polyurethane, polyester, nylon, polyethylene, polypropylene, polystyrene, polymethyl methacrylate, polycarbonate, polyformaldehyde, phenolic resin, or amino resin.

Carbon fiber is a new type of high-strength and high-modulus fiber material with a carbon content of over 95%. The carbon fiber is a microcrystalline graphite material obtained by piling up organic fibers such as flake graphite microcrystals along a fiber axial direction, and then undergoing carbonization and graphitization processing. The carbon fiber is lighter in weight than aluminum but stronger than iron and steel, possesses characteristics such as corrosion resistance and high modulus, and retains inherent properties of carbon materials while also exhibiting soft processability of textile fibers. In addition, the carbon fiber exhibits high axial strength and modulus, low density, high temperature resistance in a non-oxidizing environment, good fatigue resistance, specific heat and a conductivity between those of non-metals and metals, a small coefficient of heat expansion with anisotropic characteristics, good corrosion resistance, and good electrical and heat conducting properties and an electromagnetic shielding property.

Content of the carbon fiber filament 12 in the carbon fiber composite layer 10 is not limited in embodiments of this application. The content of the carbon fiber filament 12 may be adjusted based on parameters such as a support requirement of the display, a conductive capability required by the reinforcement plate 100, and a mechanical property of the resin layer 11.

The carbon fiber composite layer 10 includes a first surface S1 and a second surface S2 that are opposite to each other. The first surface S1 exposes a first part 121 of the carbon fiber filament 12, and the second surface S2 exposes a second part 122 of the carbon fiber filament 12.

A shape and a size of the first surface S1 and a shape and a size of the second surface S2 are not limited in embodiments of this application, and may be designed based on an actual case. For example, the first surface S1 and the second surface S2 may be rectangular.

In some examples, the carbon fiber filament 12 may include a plurality of first parts 121, and the plurality of first parts 121 are distributed at intervals. The carbon fiber filament 12 may include a plurality of second parts 122, and the plurality of second parts 122 are distributed at intervals. Quantities, distribution density, and sizes of the first part 121 and the second part 122 are not limited in embodiments of this application, and may be designed according to a conductivity requirement of the reinforcement plate 100.

Two first parts 121 at different positions may respectively belong to two different carbon fiber filaments 12. Alternatively, as shown in FIG. 1, two or more first parts 121 at different positions may belong to a same carbon fiber filament 12.

Similarly, two second parts 122 at different positions may respectively belong to two different carbon fiber filaments 12. Alternatively, as shown in FIG. 1, two or more second parts 122 at different positions may belong to a same carbon fiber filament 12.

In some examples, the first part 121 and the second part 122 may belong to a same carbon fiber filament 12, and are located at different positions of the carbon fiber filament 12.

It may be understood that there are a plurality of carbon fiber filaments 12 in the resin layer 11, some or all points of a part of the carbon fiber filaments 12 may be exposed from the first surface S1 and the second surface S2, and the other part of the carbon fiber filaments may be located on the resin layer and are not exposed.

The first conducting layer 20 is located on the first surface S1, and is in contact with the first part 121 of the carbon fiber filament 12.

The second conducting layer 30 is located on the second surface S2, and is in contact with the second part 122 of the carbon fiber filament 12. The first conducting layer 20 and the second conducting layer 30 are conducted through the carbon fiber composite layer 10.

In the reinforcement plate 100 provided in embodiments of this application, the carbon fiber composite layer 10 including the carbon fiber filament 12 is disposed. The first conducting layer 20 is in contact with the first part 121 of the carbon fiber filament 12, and the second conducting layer 30 is in contact with the second part 122 of the carbon fiber filament 12. Thanks to a good conducting property of the carbon fiber filament 12, the first conducting layer 20, the carbon fiber composite layer 10, and the second conducting layer 30 in the reinforcement plate 100 can form a good electrostatic conduction path. In this way, after the reinforcement plate 100 is bonded to a display, static electricity on the display can be effectively led out and transmitted to the ground by using the reinforcement plate 100. This reduces or avoids adverse impact caused by the static electricity on the display, and ensures normal displaying of the display.

In addition, low density of the carbon fiber composite layer 10 can contribute to low overall density of the reinforcement plate 100, thereby helping reduce a weight of the reinforcement plate 100, and reduce a weight of a display assembly and a weight of a terminal that use the reinforcement plate 100. In addition, a good heat conducting property of the carbon fiber composite layer 10 can further contribute to a good heat conducting property of the reinforcement plate 100. Therefore, after the reinforcement plate 100 is bonded to the display, heat is effectively dissipated from the display.

In some embodiments, the carbon fiber composite layer 10 further includes a heat conducting material, and the heat conducting material is disposed in the resin layer 11. A heat conductivity of the heat conducting material is higher than that of the carbon fiber filament 12, and density of the heat conducting material is lower than that of the carbon fiber filament 12.

In this embodiment of this application, the heat conducting material is disposed in the carbon fiber composite layer 10, and the heat conductivity of the heat conducting material is higher than that of the carbon fiber filament 12, so that both the carbon fiber composite layer 10 and the reinforcement plate 100 have a better heat conducting property. Therefore, after the reinforcement plate 100 is bonded to the display, heat is better dissipated from the display. In addition, the density of the heat conducting material is lower than that of the carbon fiber filament 12, so that both the carbon fiber composite layer 10 and the reinforcement plate 100 have lower density, thereby further reducing a weight of the reinforcement plate 100.

In some embodiments, the heat conducting material may be graphene.

Content of the heat conducting material in the carbon fiber composite layer 10 is not limited in embodiments of this application, and may be designed based on parameters such as density, a heat conductivity, and strength of the required reinforcement plate 100.

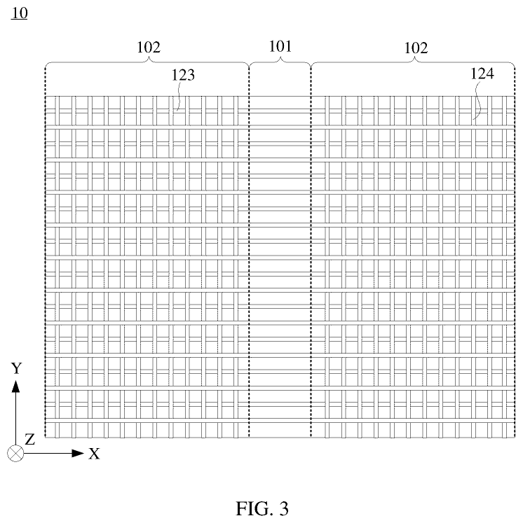

In some embodiments, as shown in FIG. 3, the carbon fiber filament 12 may include a first carbon fiber filament 123 and a second carbon fiber filament 124, and extension directions of the first carbon fiber filament 123 and the second carbon fiber filament 124 intersect.

In some examples, as shown in FIG. 3, the extension direction of the first carbon fiber filament 123 and the extension direction of the second carbon fiber filament 124 may be perpendicular to each other.

In FIG. 3, an example in which the first carbon fiber filament 123 extends in a first direction X and the second carbon fiber filament 124 extends in a second direction Y is used for illustration. Certainly, in embodiments of this application, the extension directions of the first carbon fiber filament 123 and the second carbon fiber filament 124 are not limited thereto. In some possible implementations, there may be an included angle between the extension direction of the first carbon fiber filament 123 and the first direction X, and there may also be an included angle between the extension direction of the second carbon fiber filament 124 and the first direction X.

Refer to FIG. 1 and FIG. 3. It may be understood that, although the first carbon fiber filament 123 extends in the first direction X, different parts of the first carbon fiber filament 123 may be at different positions in a direction perpendicular to the second surface S2 or in the second direction Y. Similarly, the second carbon fiber filament 124 extends in the second direction Y, and different parts of the second carbon fiber filament 124 may be at different positions in a direction perpendicular to the second surface S2 (namely, a third direction Z) or in the first direction X.

As shown in FIG. 3 and FIG. 4, a plurality of first carbon fiber filaments 123 may be arranged in the second direction Y, and a plurality of second carbon fiber filaments 124 may be arranged in the first direction X.

In some examples, as shown in FIG. 3, in the direction (namely, the third direction Z) perpendicular to the first surface S1 (the second surface S2), a plurality of first carbon fiber filaments 123 may be located above the second carbon fiber filament 124, and the other plurality of first carbon fiber filaments 123 may be located below the second carbon fiber filament 124. In this case, a part of a same second carbon fiber filament 124 may be located above the plurality of first carbon fiber filaments 123, and the other part of the second carbon fiber filament 124 may be located below the other plurality of first carbon fiber filaments 123.

Certainly, in some other examples, in the direction (namely, the third direction Z) perpendicular to the first surface S1 (the second surface S2), a plurality of second carbon fiber filaments 124 may be located above the first carbon fiber filament 123, and the other plurality of second carbon fiber filaments 124 may be located below the first carbon fiber filament 123. In this case, a part of a same first carbon fiber filament 123 may be located above the plurality of second carbon fiber filaments 124, and the other part of the first carbon fiber filament 123 may be located below the other plurality of second carbon fiber filaments 124.

Certainly, in addition to the weaving manners shown in FIG. 1 and FIG. 3, the plurality of carbon fiber filaments 12 may further have another weaving manner. Different weaving manners may correspond to different position relationships between the first carbon fiber filament 123 and the second carbon fiber filament 124. This is not limited in this application.

In some examples, the carbon fiber filament 12 in the resin layer 11 may be woven into a single-layer structure. In some other examples, the carbon fiber filament 12 in the resin layer 11 may be woven into a multi-layer structure, and a plurality of layers are connected to each other. When the carbon fiber filament 12 in the resin layer 11 is woven into a plurality of layers, different layers may be woven in a same manner or different manners.

As shown in FIG. 3, the carbon fiber composite layer 10 includes a first subpart 101 and a second subpart 102 located on two sides of the first subpart 101. The first subpart 101 includes the first carbon fiber filament 123 or the second carbon fiber filament 124, and the second subpart 102 includes the first carbon fiber filament 123 and the second carbon fiber filament 124.

In some examples, as shown in FIG. 3, the first subpart 101 includes the first carbon fiber filament 123.

In some other examples, as shown in FIG. 4, the first subpart 101 includes the second carbon fiber filament 124.

In this embodiment of this application, only one of the first carbon fiber filament 123 and the second carbon fiber filament 124 is disposed in the first subpart 101, and both the first carbon fiber filament 123 and the second carbon fiber filament 124 are disposed in the second subpart 102, so that flexibility of the first subpart 101 is better than that of the second subpart 102, and rigidity of the second subpart 102 is better than that of the first subpart 101. When the display supported by the reinforcement plate 100 is a flexible display, the display may include a foldable region and two non-foldable regions that are respectively disposed on two sides of the foldable region. In this way, after the reinforcement plate 100 is bonded to the display, the first part 101 of the carbon fiber composite layer 10 of the reinforcement plate 100 can be folded along with the foldable region of the display, and the second part 102 of the carbon fiber composite layer 10 of the reinforcement plate 100 can support the non-foldable regions of the display when the display is folded or unfolded, thereby improving reliability of the reinforcement plate 100.

In some examples, when the first subpart 101 includes the first carbon fiber filament 123, a quantity of first carbon fiber filaments 123 in the first subpart 101 may be less than a quantity of first carbon fiber filaments 123 in the second subpart 102. In some other examples, when the first subpart 101 includes the second carbon fiber filament 124, a quantity of second carbon fiber filaments 124 in the first subpart 101 may be less than a quantity of second carbon fiber filaments 124 in the second subpart 102.

In this way, by reducing the quantity of first carbon fiber filaments 123 or second carbon fiber filaments 124 in the first subpart 101, flexibility of the first part 101 of the carbon fiber composite layer 10 can be further improved, and flexibility of a part that is of the reinforcement plate 100 and that corresponds to the first part 101 can be improved.

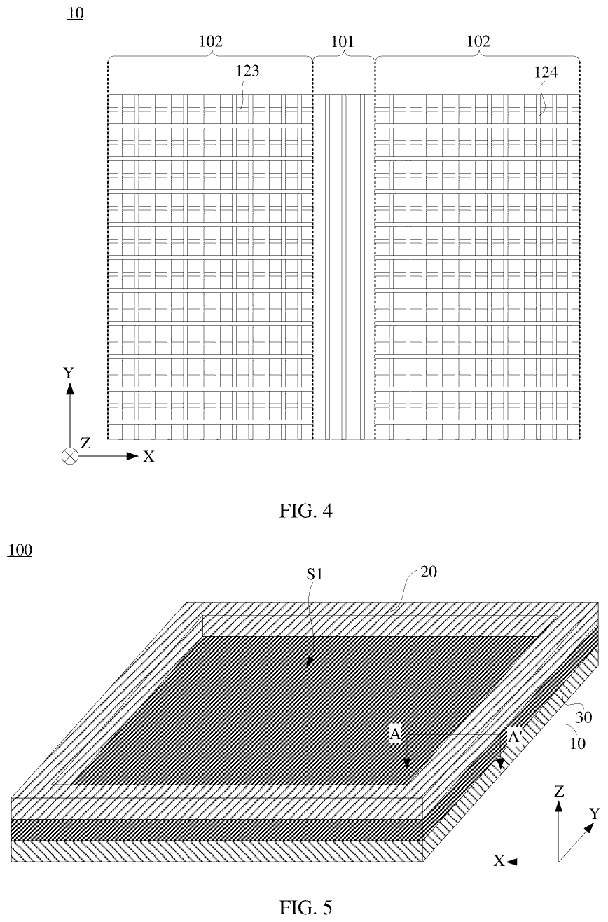

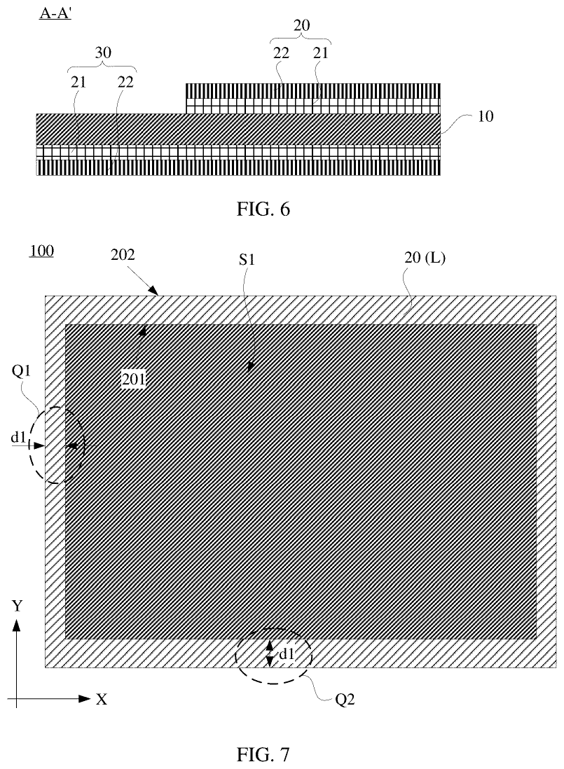

FIG. 5 is a diagram of a three-dimensional structure of a reinforcement plate 100 according to an embodiment of this application. FIG. 6 is a cross sectional schematic view of the reinforcement plate 100 shown in FIG. 5 at A-A′. To simplify the accompanying drawings, the resin layer 11 and the carbon fiber filament 12 in the carbon fiber composite layer 10 are not shown in FIG. 5 and FIG. 6.

In some embodiments, as shown in FIG. 5 and FIG. 6, both the first conducting layer 20 and the second conducting layer 30 include a transition layer 21 and a metal layer 22 that are disposed in a stacked manner, and the transition layer 21 is located between the metal layer 22 and the carbon fiber composite layer 10. A material of the transition layer 21 includes at least one of titanium, nickel, chromium, molybdenum, or tungsten.

For example, a material of the metal layer 22 may include nickel, gold, silver, and the like. It may be understood that the material of the metal layer 22 in this embodiment of this application is not limited thereto.

Thicknesses of the transition layer 21 and the metal layer 22 are not limited in embodiments of this application, and may be designed according to different requirements.

When the material of the transition layer 21 includes at least one of titanium, nickel, chromium, molybdenum, or tungsten, the transition layer 21 can be better combined to the carbon fiber filament 12 exposed from the first surface S1 and the second surface S2 that are of the carbon fiber composite layer 10. In addition, the transition layer 21 can be better bonded to the metal layer 22, so that the first conducting layer 20 and the second conducting layer 30 are tightly combined to the carbon fiber composite layer 10, thereby improving structural stability and reliability of the reinforcement plate 100.

In some embodiments, as shown in FIG. 5 and FIG. 7, a projection of the first conducting layer 20 on the first surface S1 of the carbon fiber composite layer 10 is an annulus L. The annulus L includes an inner edge 201 and an outer edge 202, and the outer edge 202 of the annulus L coincides with an edge of the first surface S1.

When the first conducting layer 20 includes the transition layer 21 and the metal layer 22 that are disposed in a stacked manner, orthographic projections of the transition layer 21 and the metal layer 22 on the first surface S1 are both an annulus.

It may be understood that “the outer edge 202 of the annulus L coincides with the edge of the first surface S1” not only includes a case in which the outer edge 202 of the annulus L completely coincides with the edge of the first surface S1, but also includes a case in which the outer edge 202 of the annulus L approximately coincides with the edge of the first surface S1.

The expression “approximately coincides with” described herein means that a spacing may exist between the outer edge 202 of the annulus and the edge of the first surface S1, and the spacing is within an acceptable deviation range. The acceptable deviation range is determined by a person of ordinary skill in the art by considering an error (namely, a limitation of a measurement system) related to measurement being discussed and measurement of a specific quantity.

In some embodiments, a width d1 of the annulus L may be less than or equal to 20 millimeters. For example, the width d1 of the annulus L may be 5 millimeters, 10 millimeters, 15 millimeters, 20 millimeters, or the like.

It may be understood that the width d1 of the annulus L is a minimum distance from any point on the inner edge 201 of the annulus L to the outer edge 202 of the annulus L, or a minimum distance from any point on the outer edge 202 of the annulus L to the inner edge 201 of the annulus L.

The width d1 of the annulus L is less than or equal to 20 millimeters, so that a projection area of the first conducting layer 20 on the first surface S1 is small. Therefore, when the reinforcement plate 100 is bonded to the display, interference caused by existence of the first conducting layer 20 to a circuit in the display is reduced.

When the projection of the first conducting layer 20 on the first surface S1 is an annulus, the first surface S1 may include a first sub-surface in contact with the first conducting layer 20 and a second sub-surface not in contact with the first conducting layer 20. In this case, the first sub-surface of the first surface S1 may expose the first part 121 of the carbon fiber filament 12, or both the first sub-surface and the second sub-surface of the first surface S1 may expose the first part 121 of the carbon fiber filament 12.

In some embodiments, the width of the annulus L may be equal everywhere. In this way, the first conducting layer 20 has a uniform size, and conductive capabilities at different positions of the first conducting layer 20 are the same or approximately the same. After the reinforcement plate 100 is bonded to the display, the first conducting layer 20 can effectively guide static electricity at different positions of the display to the ground.

In some other examples, widths of the annulus L may be different at different positions. For example, as shown in FIG. 7, at a position Q1 and a position Q2 of the annulus L, the widths of the annulus L are not equal.

In this way, at a position of the annulus L, a width of the annulus L may be large, so that a resistance at a corresponding position of the first conducting layer 20 is small. In addition, at another position of the annulus L, a width of the annulus L may be small, to address a problem that a display effect of the display is poor because existence of the first conducting layer interferes with a circuit structure of a light emitting device in the display.

A shape and a size of a projection of the second conducting layer 30 on the second surface S2 are not limited in embodiments of this application. For example, a shape of the projection of the second conducting layer 30 on the second surface S2 may be the same as a shape of the second surface S2, and a size of the projection of the second conducting layer 30 on the second surface S2 is also the same as a size of the second surface S2. Alternatively, the projection of the second conducting layer 30 on the second surface S2 may also be an annulus. Alternatively, the projection of the second conducting layer 30 on the second surface S2 may be in a grid shape.

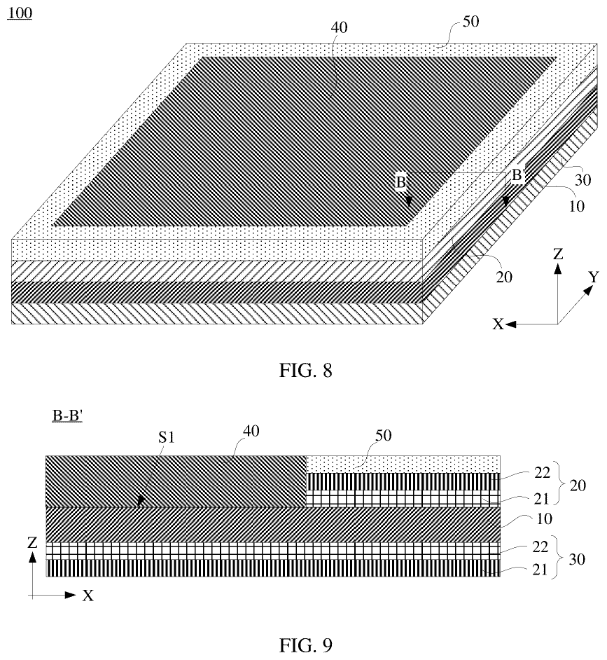

FIG. 8 is a diagram of a three-dimensional structure of a reinforcement plate 100 according to an embodiment of this application. FIG. 9 is a cross sectional schematic view of the reinforcement plate 100 shown in FIG. 8 at B-B′. To simplify the accompanying drawings, the resin layer 11 and the carbon fiber filament 12 in the carbon fiber composite layer 10 are not shown in both FIG. 8 and FIG. 9.

In some embodiments, as shown in FIG. 8 and FIG. 9, the reinforcement plate 100 further includes a first insulation layer 40, and the first insulation layer 40 is located on the first surface S1 of the carbon fiber composite layer 10. The first conducting layer 20 surrounds the first insulation layer 40, and is in contact with the first insulation layer 40. The first insulation layer 40 may be configured to bond the reinforcement plate 100 to the display.

For example, a material of the first insulation layer 40 may include optically clear adhesive (OCA).

In some embodiments, as shown in FIG. 8 and FIG. 9, the reinforcement plate 100 further includes a conductive adhesive layer 50. The conductive adhesive layer 50 is located on a side that is of the first conducting layer 20 and that is away from the carbon fiber composite layer 10. The conductive adhesive layer 50 is disposed, so that the reinforcement plate 100 can be better connected to the display, thereby improving connection stability between the reinforcement plate 100 and the display.

In some examples, as shown in FIG. 9, a surface that is of the first insulation layer 40 and that is away from the carbon fiber composite layer 10 is flush with or approximately flush with a surface that is of the conductive adhesive layer 50 and that is away from the carbon fiber composite layer 10.

The expression “approximately flush with” means that a difference may exist between a height of the surface that is of the first insulation layer 40 and that is away from the carbon fiber composite layer 10 and a height of the surface that is of the conductive adhesive layer 50 and that is away from the carbon fiber composite layer 10, but the difference is within an acceptable deviation range. The acceptable deviation range is determined by a person of ordinary skill in the art by considering an error (namely, a limitation of a measurement system) related to measurement being discussed and measurement of a specific quantity.

The surface that is of the first insulation layer 40 and that is away from the carbon fiber composite layer 10 is flush with the surface that is of the conductive adhesive layer 50 and that is away from the carbon fiber composite layer 10, so that a surface on which the reinforcement plate 100 is bonded to the display is flat. Therefore, after the reinforcement plate 100 is bonded to the display, the display is not susceptible to the negative problem of a screen film imprint, thereby ensuring a display effect of the display.

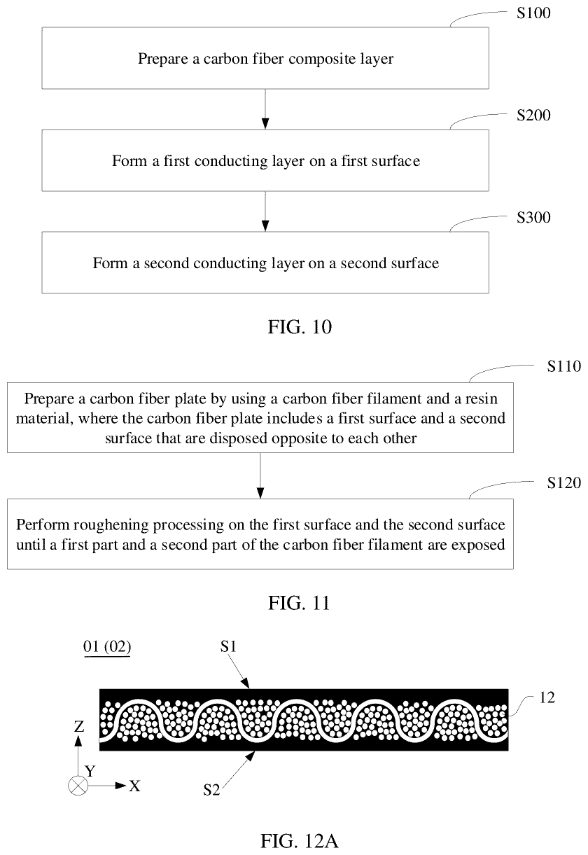

As shown in FIG. 10, an embodiment of this application provides a preparation method for a reinforcement plate 100. The preparation method includes the following steps.

S100: Prepare a carbon fiber composite layer 10, where the carbon fiber composite layer 10 includes a resin layer 11 and a carbon fiber filament 12 disposed in the resin layer 11. The carbon fiber composite layer 10 includes a first surface S1 and a second surface S2 that are opposite to each other, the first surface S1 exposes a first part 121 of the carbon fiber filament 12, and the second surface S2 exposes a second part 122 of the carbon fiber filament 12.

In some examples, as shown in FIG. 11, preparing the carbon fiber composite layer 10 includes the following steps:

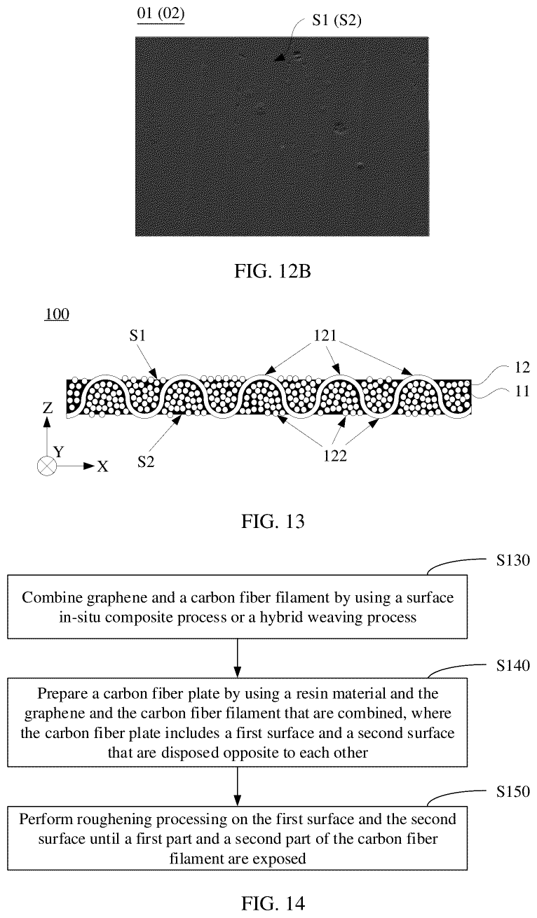

S110: As shown in FIG. 12A and FIG. 12B, prepare a carbon fiber plate 01 by using the carbon fiber filament 12 and a resin material, where the carbon fiber plate 01 includes the first surface S1 and the second surface S2 that are disposed opposite to each other. In this case, as shown in FIG. 12A and FIG. 12B, the first surface S1 and the second surface S2 do not expose the carbon fiber filament 12.

For example, the carbon fiber filament 12 and the resin material may be provided first, and then the carbon fiber plate 01 is formed by performing steps such as adhesive coating and compression molding.

S120: With reference to FIG. 2 and FIG. 13, perform roughening processing on the first surface S1 and the second surface S2 until the first part 121 and the second part 122 of the carbon fiber filament 12 are exposed. In this case, the first surface S1 exposes the first part 121 of the carbon fiber filament 12, and the second surface S2 exposes the second part 122 of the carbon fiber filament 12.

For example, roughening processing may be performed on the first surface S1 and the second surface S2 by using a liquid phase oxidation etching process, a plasma processing process, or an irradiation processing process.

In some examples, the carbon fiber composite layer 10 may further include a heat conducting material, the heat conducting material is disposed in the resin layer 11, a heat conductivity of the heat conducting material is higher than that of the carbon fiber filament 12, and density of the heat conducting material is lower than that of the carbon fiber filament 12.

The heat conducting material may include, for example, graphene.

Based on this, in some other examples, as shown in FIG. 14, preparing the carbon fiber composite layer 10 includes the following steps.

S130: Combine the graphene and the carbon fiber filament 12 by using a surface in-situ composite process or a hybrid weaving process.

S140: With reference to FIG. 12A, prepare a carbon fiber plate 02 by using the resin material and the graphene and the carbon fiber filament that are combined. The carbon fiber plate 02 includes the first surface S1 and the second surface S2 that are disposed opposite to each other. In this case, with reference to FIG. 12A and FIG. 12B, the first surface S1 and the second surface S2 also do not expose the carbon fiber filament 12.

S150: With reference to FIG. 13, perform roughening processing on the first surface S1 and the second surface S2 until the first part 121 and the second part 122 of the carbon fiber filament 12 are exposed. In other words, the first surface S1 exposes the first part 121 of the carbon fiber filament 12, and the second surface S2 exposes the second part 122 of the carbon fiber filament 12.

Refer to FIG. 1. The reinforcement plate 100 further includes a first conducting layer 20 located on the first surface S1 of the carbon fiber composite layer 10. In this way, as shown in FIG. 10, after step S100 of preparing the carbon fiber composite layer 10, the preparation method may further include the following step.

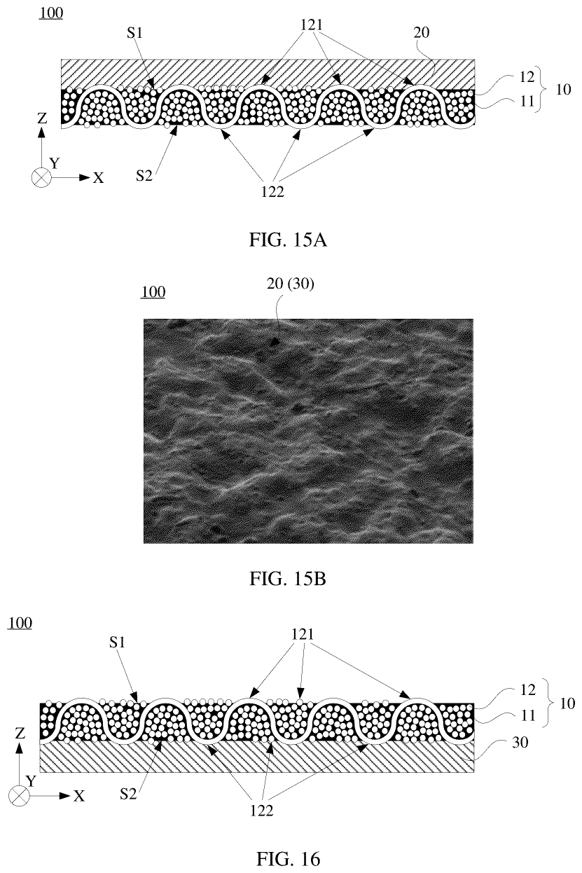

S200: As shown in FIG. 15A and FIG. 15B, form the first conducting layer 20 on the first surface S1, where the first conducting layer 20 is in contact with the first part 121 of the carbon fiber filament 12.

For example, the first conducting layer 20 may be formed on the first surface S1 by using a sputtering process. In this way, a binding force between the first conducting layer 20 and the carbon fiber composite layer 10 may be stronger, so that the first conducting layer 20 is less likely to be detached from the carbon fiber composite layer 10 or separated from the carbon fiber composite layer 10, thereby improving reliability of the reinforcement plate 100.

Still refer to FIG. 1. The reinforcement plate 100 further includes a second conducting layer 30 located on the second surface S2 of the carbon fiber composite layer 10. In this way, as shown in FIG. 10, after step S100 of preparing the carbon fiber composite layer 10, the preparation method may further include the following step.

S300: As shown in FIG. 1 and FIG. 16, form the second conducting layer 30 on the second surface S2, where the second conducting layer 30 is in contact with the second part 122 of the carbon fiber filament 12. The first conducting layer 20 and the second conducting layer 30 are conducted through the carbon fiber composite layer 10.

For example, the second conducting layer 30 may be formed on the second surface S2 by using a sputtering process. In this way, a binding force between the second conducting layer 30 and the carbon fiber composite layer 10 may be stronger, so that the second conducting layer 30 is less likely to be detached from the carbon fiber composite layer 10 or separated from the carbon fiber composite layer 10, thereby improving reliability of the reinforcement plate 100.

A sequence of forming the first conducting layer 20 and the second conducting layer 30 is not limited in embodiments of this application. Refer to FIG. 15A and FIG. 1. The first conducting layer 20 may be first formed on the first surface S1, and then the second conducting layer 30 is formed on the second surface S2. Refer to FIG. 16 and FIG. 1. The second conducting layer 30 may be first formed on the second surface S2, and then the first conducting layer 20 is formed on the first surface S1.

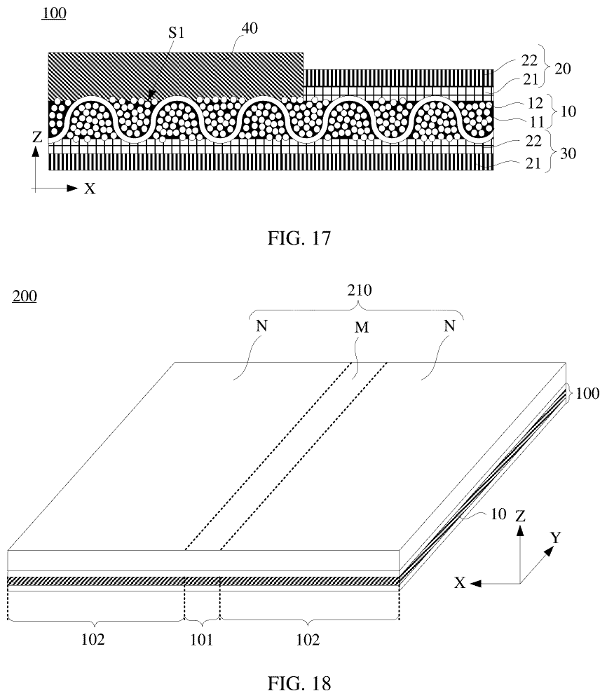

In some embodiments, as shown in FIG. 17, the preparation method may further include: forming a first insulation layer 40 on the first surface S1.

A formation sequence of the first insulation layer 40 and the first conducting layer 20 is not limited in embodiments of this application, provided that the first conducting layer 20 can surround the first insulation layer 40 and be in contact with the first insulation layer 40. For example, after the first conducting layer 20 is formed on the first surface S1, the first insulation layer 40 may be formed on the first surface S1. For another example, the first insulation layer 40 may be first formed on the first surface S1, and then the first conducting layer 20 is formed on the first surface S1.

In some embodiments, refer to FIG. 9. The preparation method may further include: forming a conductive adhesive layer 50 on a side that is of the first conducting layer 20 and that is away from the carbon fiber composite layer 10.

In some examples, a surface that is of the conductive adhesive layer 50 and that is away from the carbon fiber composite layer 10 may be flush with a surface that is of the first insulation layer 40 and that is away from the carbon fiber composite layer.

As shown in FIG. 18, some embodiments of this application provide a display assembly 200. The display assembly 200 includes a display 210 and a reinforcement plate 100. The reinforcement plate 100 is located on a non-display side of the display 210, and is bonded to the display 210. The reinforcement plate 100 is configured to support the display 210.

Length and width sizes of the display 210 may be consistent with or basically consistent with those of the reinforcement plate 100. The length size may be a size of the display 210 or the reinforcement plate 100 in a first direction X, and the width size may be a size of the display 210 or the reinforcement plate 100 in a second direction Y. Thicknesses (a size in a third direction Z) of the display 210 and the reinforcement plate 100 are not limited in embodiments of this application, and may be designed according to an actual requirement.

In some embodiments, as shown in FIG. 18, the display 210 may be a flexible display. The display 210 includes a foldable region M and two non-foldable regions N, and the two non-foldable regions N are respectively located on two sides of the foldable region M.

The flexible display has a characteristic of being foldable, and the display 210 may be folded in the foldable region M, to fold and unfold the display 210. Two opposite surfaces of the non-foldable region N are both planes, and remain unchanged in a folding and unfolding process of the display 210.

It may be understood that the display 210 provided in this embodiment of this application may include one foldable region M and two non-foldable regions N, or may include a plurality of foldable regions M, and non-foldable regions N disposed on two sides of each foldable region M.

In some embodiments, as shown in FIG. 18, the reinforcement plate 100 includes a carbon fiber composite layer 10. The carbon fiber composite layer 10 includes a first subpart 101 and a second subpart 102 located on two sides of the first subpart 101. The first subpart 101 of the carbon fiber composite layer 10 corresponds to the foldable region M of the display 200, and the second subpart 102 of the carbon fiber composite layer 10 corresponds to the non-foldable region N of the display 200.

As described above, a carbon fiber filament 12 includes a first carbon fiber filament 123 and a second carbon fiber filament 124, and extension directions of the first carbon fiber filament 123 and the second carbon fiber filament 124 intersect. The first subpart 101 includes the first carbon fiber filament 123 or the second carbon fiber filament 124, and the second subpart 102 includes the first carbon fiber filament 123 and the second carbon fiber filament 124.

Because the carbon fiber filament 12 in the first subpart 101 extends in a single direction, flexibility of the first subpart 101 is better than that of the second subpart 102. In this way, the first subpart 101 corresponds to the foldable region M of the display 200, facilitating folding and unfolding of the reinforcement plate 100 along with the display 200.

Because the second subpart 102 includes the first carbon fiber filament 123 and the second carbon fiber filament 124 that extend in different directions, rigidity of the second subpart 102 is better than that of the first subpart 101. In this way, the second subpart 102 corresponds to the non-foldable region N of the display 200, which helps the reinforcement plate 100 support the non-foldable region N of the display 200 when the display 200 is folded and unfolded.

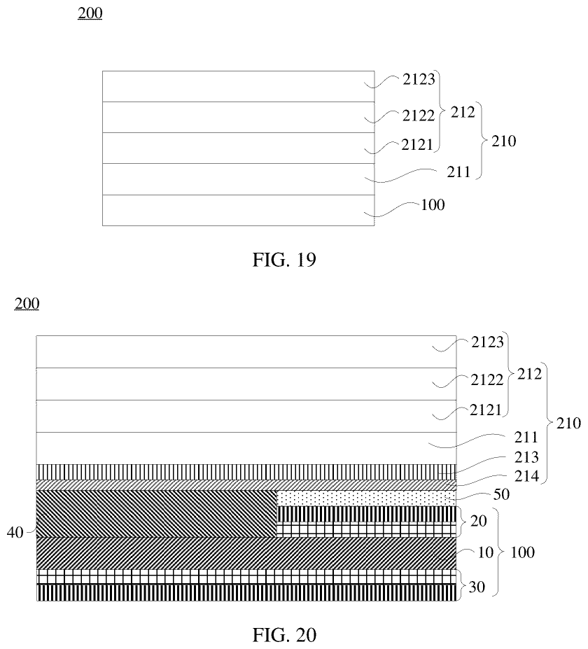

In some embodiments, the display 210 may be an organic light emitting diode (OLED) display. In this case, as shown in FIG. 19, the display 210 may include a substrate 211 and a light emitting device 212, and the light emitting device 212 is located on the substrate 211.

To facilitate folding of the display 210, a material of the substrate 211 may include a flexible material such as polyimide (polyimide, PI).

In some examples, the display 210 may include a plurality of light emitting devices 212. Colors of light emitted by the plurality of light emitting devices 212 may be different, or may be the same. When the colors of the light emitted by the plurality of light emitting devices 212 are different, the colors of the light emitted by the plurality of light emitting devices 212 may include, for example, red, blue, and green. Alternatively, when the colors of the light emitted by the plurality of light emitting devices 212 are different, the colors of the light emitted by the plurality of light emitting devices 212 may include, for example, red, blue, green, and white. Certainly, the colors of the light emitted by the light emitting device 212 may not be limited thereto.

A distribution manner of the plurality of light emitting devices 212 on the substrate 211 and a quantity of the plurality of light emitting devices 212 are not limited in embodiments of this application, both of which may be designed according to an actual requirement.

Still refer to FIG. 19. In some examples, the light emitting device 212 may include an anode layer 2121, a light emitting layer 2122, and a cathode layer 2123 that are disposed in a stacked manner and that are sequentially away from the substrate 211. The anode layer 2121 and the cathode layer 2123 are configured to drive the light emitting layer 2122 to emit light.

In some examples, the light emitting device 212 may further include a hole transport layer (not shown) located between the light emitting layer 2122 and the anode layer 2121, and an electron transport layer (not shown) located between the light emitting layer 2122 and the cathode layer 2123. The electron transport layer and the hole transport layer are disposed, so that carriers can be evenly injected into the light emitting layer 2122, thereby improving light emitting efficiency of the light emitting device 212.

In some embodiments, to provide a voltage difference for the anode layer 2121 and the cathode layer 2123, the display 210 may further include a drive circuit layer disposed on the substrate 211.

In this embodiment of this application, as shown in FIG. 19, the reinforcement plate 100 is located on the non-display side of the display 210, that is, the reinforcement plate 100 is located on a side that is of the substrate 211 and that is away from the light emitting device 212.

In some embodiments, as shown in FIG. 20, the display 200 may further include a second insulation layer 213 and a metal sheet 214. The second insulation layer 213 is located on the side that is of the substrate 211 and that is away from the light emitting device 212, and the metal sheet 214 is located on a side that is of the second insulation layer and that is away from the substrate 211. The metal sheet 214 is bonded to the reinforcement plate 100.

For example, a material of the second insulation layer 213 may be optically clear adhesive (OCA).

For example, length and width sizes of the second insulation layer 213 may be the same as those of the substrate 211.

For example, length and width sizes of the metal sheet 214 may also be the same as those of the substrate 211.

Thicknesses of the second insulation layer 213 and the metal sheet 214 are not limited in embodiments of this application, and may be designed according to an actual requirement.

In some examples, as shown in FIG. 20, the reinforcement plate 100 includes a first insulation layer 40 and a conductive adhesive layer 50, and the metal sheet 214 is bonded to the first insulation layer 40 and the conductive adhesive layer 50 in the reinforcement plate 100. For structural functions of the first insulation layer 40 and the conductive adhesive layer 50, refer to the foregoing embodiments of this specification. Details are not described herein again.

In this embodiment of this application, the second insulation layer 213 and the metal sheet 214 are disposed in the display 210, and the metal sheet 214 is bonded to the first insulation layer 40 and the conductive adhesive layer 50 of the reinforcement plate 100. This can avoid a problem of a nonlinear effect caused by direct contact between metals (that is, direct contact between the metal sheet 214 and the first conducting layer 20), as well as nonlinear excitation and a passive intermodulation (PIM) effect. In addition, this implements reliable grounding of the display 210 without nonlinear excitation or a PIM effect, while reducing electromagnetic compatibility (EMC) noise or addressing a signal feed grounding issue.

An embodiment of this application provides a terminal. The terminal may be an electronic device such as a tablet computer, a mobile phone, an e-reader, a remote control, a personal computer (, PC), a notebook computer, a personal digital assistant (PDA), a vehicle-mounted device, a web television, a wearable device, or a television, or may be an electrical device used in the aerospace field, the military industry field, or the like, or may be a communication device used in the communication field. A specific form of the device is not particularly limited in embodiments of this application.

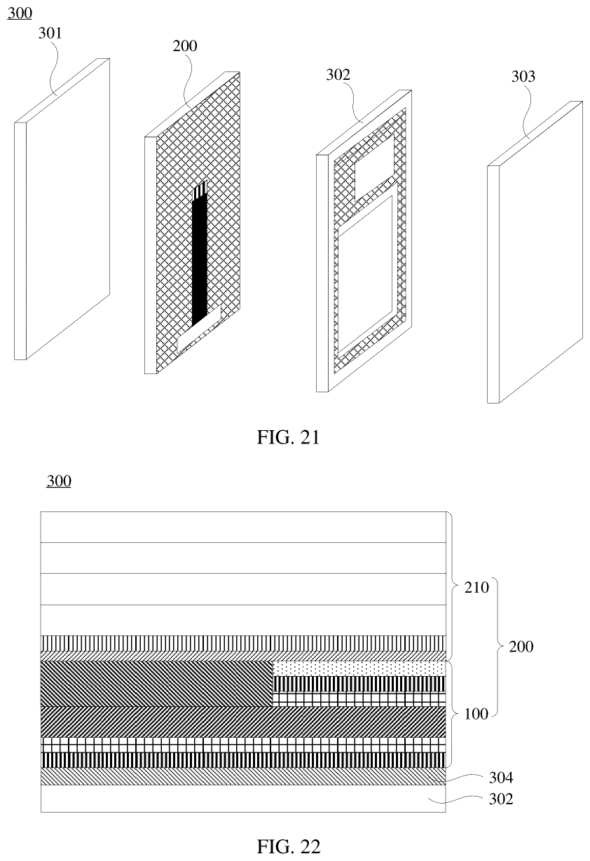

For ease of description, the following uses an example in which the terminal is a mobile phone for description. As shown in FIG. 21, a terminal 300 may include a cover 301, a display assembly 200, a middle frame 302, and a housing 303. Both the display assembly 200 and the middle frame 302 are disposed in the housing 303, the middle frame 302 is located on a non-display side of the display assembly 200, and the cover 301 is located on a side that is of the display assembly 200 and that is away from the middle frame 302.

Both the cover 301 and the housing 303 are configured to protect the display assembly 200 and the middle frame 302.

A surface that is of the middle frame 302 and that is away from the display assembly 200 may be used to install internal components such as a mainboard, a battery, a camera, and an antenna. The mainboard may be, for example, a printed circuit board (PCB). The mainboard is configured to provide an electrical signal for the display assembly 200. For example, the display assembly 200 may be electrically connected to the mainboard by using a flexible printed circuit (FPC) board.

In some embodiments, as shown in FIG. 22, the terminal 300 may further include an electrical connector 304. The electrical connector 304 is located between the display assembly 200 and the middle frame 302. The reinforcement plate 100 of the display assembly 200 is connected to the middle frame 302 through the electrical connector 304.

For example, the electrical connector 304 may include conductive foam.

In this way, static electricity on the display 210 may be transmitted to the middle frame 302 for grounding through the reinforcement plate 100 and the electrical connector 304, thereby helping reduce adverse impact of the static electricity on the display.

In the descriptions of this specification, the described specific features, structures, materials, or characteristics may be combined in a proper manner in any one or more of embodiments or examples.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A reinforcement plate, comprising:
a carbon fiber composite layer, comprising a resin layer and a carbon fiber filament disposed in the resin layer, wherein the carbon fiber composite layer comprises a first surface, wherein the first surface exposes a first part of the carbon fiber filament;
a first conducting layer, located on the first surface and in contact with the first part of the carbon fiber filament.

2. The reinforcement plate according to claim 1, wherein the carbon fiber composite layer further comprises a heat conducting material, wherein the heat conducting material is disposed in the resin layer, wherein a heat conductivity of the heat conducting material is higher than that of the carbon fiber filament, and wherein a density of the heat conducting material is lower than a density of the carbon fiber filament.

3. The reinforcement plate according to claim 2, wherein the heat conducting material is graphene.

4. The reinforcement plate according to claim 1, wherein the carbon fiber filament comprises a first carbon fiber filament and a second carbon fiber filament, and wherein extension directions of the first carbon fiber filament and the second carbon fiber filament intersect; and
wherein the carbon fiber composite layer comprises a first subpart and a second subpart located on two sides of the first subpart, wherein the first subpart comprises the first carbon fiber filament or the second carbon fiber filament, and wherein the second subpart comprises the first carbon fiber filament and the second carbon fiber filament.

5. The reinforcement plate according to claim 1, wherein the first conducting layer comprises a transition layer and a metal layer that are disposed in a stacked manner, wherein the transition layer is located between the metal layer and the carbon fiber composite layer, and wherein a material of the transition layer comprises at least one of titanium, nickel, chromium, molybdenum, or tungsten.

6. The reinforcement plate according to claim 1, wherein a projection of the first conducting layer on the first surface is an annulus, wherein the annulus comprises an inner edge and an outer edge, and the outer edge of the annulus coincides with an edge of the first surface.

7. The reinforcement plate according to claim 6, wherein a width of the annulus is less than or equal to 20 millimeters.

8. The reinforcement plate according to claim 1, further comprising:
a first insulation layer, located on the first surface, wherein the first conducting layer surrounds the first insulation layer and is in contact with the first insulation layer.

9. The reinforcement plate according to claim 8, further comprising:
a conductive adhesive layer, located on a side that is of the first conducting layer and that is away from the carbon fiber composite layer.

10. The reinforcement plate according to claim 9, wherein a surface that is of the conductive adhesive layer and that is away from the carbon fiber composite layer is flush with a surface that is of the first insulation layer and that is away from the carbon fiber composite layer.

11. A display assembly, comprising:
a display; and
a reinforcement plate that comprises:
a carbon fiber composite layer, comprising a resin layer and a carbon fiber filament disposed in the resin layer, wherein the carbon fiber composite layer comprises a first surface, wherein the first surface exposes a first part of the carbon fiber filament; and
a first conducting layer, located on the first surface and in contact with the first part of the carbon fiber filament;
wherein the reinforcement plate is located on a non-display side of the display and is bonded to the display.

12. The display assembly according to claim 11, wherein the display is a flexible display, wherein the display comprises a foldable region and two non-foldable regions, and wherein the two non-foldable regions are respectively located on two sides of the foldable region; and
wherein the reinforcement plate comprises a carbon fiber composite layer, wherein the carbon fiber composite layer comprises a first subpart and a second subpart, wherein the first subpart corresponds to the foldable region, and wherein the second subpart corresponds to the non-foldable region.

13. The display assembly according to claim 12, wherein the carbon fiber filament comprises a first carbon fiber filament and a second carbon fiber filament, and wherein extension directions of the first carbon fiber filament and the second carbon fiber filament intersect; and
wherein the second subpart is located on two sides of the first subpart, wherein the first subpart comprises the first carbon fiber filament or the second carbon fiber filament, and wherein the second subpart comprises the first carbon fiber filament and the second carbon fiber filament.

14. The display assembly according to claim 11, wherein the display comprises:
a substrate;
a light emitting device, located on the substrate;
an insulation layer, located on a side that is of the substrate and that is away from the light emitting device; and
a metal sheet, located on a side that is of the second insulation layer and that is away from the substrate, wherein the metal sheet is bonded to the reinforcement plate.

15. The display assembly according to claim 11, wherein the first conducting layer comprises a transition layer and a metal layer that are disposed in a stacked manner, wherein the transition layer is located between the metal layer and the carbon fiber composite layer, and wherein a material of the transition layer comprises at least one of titanium, nickel, chromium, molybdenum, or tungsten.

16. A terminal, comprising:
a housing; and
a reinforcement plate disposed in the housing, wherein the reinforcement plate comprises:
a carbon fiber composite layer, comprising a resin layer and a carbon fiber filament disposed in the resin layer, wherein the carbon fiber composite layer comprises a first surface, wherein the first surface exposes a first part of the carbon fiber filament; and
a first conducting layer, located on the first surface and in contact with the first part of the carbon fiber filament.

17. The terminal according to claim 16, further comprising:
a display, wherein the reinforcement plate is located on a non-display side of the display and is bonded to the display.

18. The terminal according to claim 17, further comprising:
a middle frame, disposed in the housing and located on the non-display side of the display; and
an electrical connector, wherein the reinforcement plate is connected to the middle frame through the electrical connector.

19. The terminal according to claim 17, wherein the display is a flexible display, wherein the display comprises a foldable region and two non-foldable regions, and wherein the two non-foldable regions are respectively located on two sides of the foldable region; and
wherein the reinforcement plate comprises a carbon fiber composite layer, wherein the carbon fiber composite layer comprises a first subpart and a second subpart, wherein the first subpart corresponds to the foldable region, and wherein the second subpart corresponds to the non-foldable region; wherein the carbon fiber filament comprises a first carbon fiber filament and a second carbon fiber filament, and wherein extension directions of the first carbon fiber filament and the second carbon fiber filament intersect; and
wherein the second subpart is located on two sides of the first subpart, wherein the first subpart comprises the first carbon fiber filament or the second carbon fiber filament, and wherein the second subpart comprises the first carbon fiber filament and the second carbon fiber filament.

20. The terminal according to claim 16, wherein the first conducting layer comprises a transition layer and a metal layer that are disposed in a stacked manner, wherein the transition layer is located between the metal layer and the carbon fiber composite layer, and wherein a material of the transition layer comprises at least one of titanium, nickel, chromium, molybdenum, or tungsten.
